(19) United States
(12) Patent Application Publication
(10) Pub. No.: US 2004/0158437 A1
(43) Pub. Date: Aug. 12, 2004

(54) Method and device for extracting a signal identifier, method and device for creating a database from signal identifiers and method and device for referencing a search time signal

(76) Inventors: Frank Klefenz, Mannheim (DE); Karlheinz Brandenburg, Erlangen (DE); Wolfgang Hirsch, Weimar (DE); Christian Uhle, Ilmenau (DE); Christian Richter, Ilmenau (DE); Andras Katai, Ilmenau (DE); Matthias Kaufmann, Ilmenau (DE)

Correspondence Address: BEYER WEAVER & THOMAS LLP, P.O. BOX 778, BERKELEY, CA, 94704-0778, US

(21) Appl. No.: 10/473,801

(22) PCT Filed: Mar. 12, 2002
(86) PCT No.: PCT/EP02/02703

(30) Foreign Application Priority Data
Apr. 10, 2001 (DE) 101 17 871.9

(51) Int. Cl. H03F 1/26

(52) U.S. Cl. 702/189

(57) ABSTRACT

In a method of extracting a signal identifier from a time signal, the temporal occurrence of signal edges in the time signal is detected (12), wherein a signal edge has a specified temporal length. In addition, the temporal interval between two selected detected signal edges is determined (14). From the temporal interval determined, a frequency value is calculated (16), the frequency value being associated with a time of occurrence of the frequency value in the time signal so as to obtain a coordinate tuple from the frequency value and the time of occurrence for this frequency value. A signal identifier is created from a plurality of coordinate tuples (18), each coordinate tuple including a frequency value and a time of occurrence, which is why the signal identifier includes a sequence of signal identifier values reproducing the temporal form of the time signal. The extracted signal identifier is based on signal edges of the time signal and thus reproduces the temporal form of the time signal. The signal identifier is therefore characteristic of the time signal, on the one hand, and robust towards changes in the time signal, on the other hand.

The present invention relates to the processing of time signals having a harmonic portion, and in particular to creating a signal identifier for a time signal so as to be able to describe the time signal by means of a database wherein a plurality of signal identifiers are stored for a plurality of time signals.

Concepts by means of which time signals having a harmonic portion, such as audio data, are identifiable and able to be referenced are useful for many users. Especially in a situation where there is an audio signal whose title and author are unknown, it is often desirable to find out who the respective song originates from. A need for this exists, for example, if there is a desire to acquire, e.g., a CD of the performer in question. If the present audio signal includes only the time-signal content but no name concerning the performer, the music publishers, etc.,. no identification of the origin of the audio signal or of the person or institution a song originates from will be possible. The only hope then has been to hear the audio piece once again, including reference data with regard to the author or the source where the audio signal is to be purchased, so as to be able to procure the song desired.

It is not possible to search audio data using conventional search machines on the Internet since the search engine know only how to deal with textual data. Audio signals, or, more generally speaking, time signals having a harmonic portion may not be processed by such search engines unless they include textual search indications.

A realistic stock of audio files comprises several thousand stored audio files up to hundred thousands of audio files. Music database information may be stored on a central Internet server, and potential search enquiries may be effected via the Internet. Alternatively, with today's hard disc capacities, it would also be feasible to have these central music databases on users' local hard disc systems. It is desirable to be able to browse such music databases to obtain reference data about an audio file of which only the file itself but no reference data is known.

In addition, it is equally desirable to be able to browse music databases using specified criteria, for example such as to be able to find out similar pieces. Similar pieces are, for example, such pieces which have a similar tune, a similar set of instruments or simply similar sounds, such as, for example, the sound of the sea, bird sounds, male voices, female voices, etc.

The U.S. Pat. No. 5,918,223 discloses a method and an apparatus for a content-based analysis, storage, retrieval and segmentation of audio information. This method is based on extracting several acoustic features from an audio signal. What is measured are volume, bass, pitch, brightness, and Mel-frequency-based Cepstral coefficients in a time window of a specific length at periodic intervals. Each set of measuring data consists of a series of feature vectors measured. Each audio file is specified by the complete set of the feature sequences calculated for each feature. In addition, the first derivations are calculated for each sequence of feature vectors. Then statistical values such as the mean value and the standard deviation are calculated. This set of values is stored in an N vector, i.e. a vector with n elements. This procedure is applied to a plurality of audio files to derive an N vector for each audio file. In doing so, a database is gradually built from a plurality of N vectors. A search N vector is then extracted from an unknown audio file using the same procedure. In a search enquiry, a calculation of the distance of the specified N vector and the N vectors stored in the database is then determined. Finally, that N vector which is at the minimum distance from the search N vector is output. The N vector output has data about the author, the title, the supply source, etc. associated with it, so that an audio file may be identified with regard to its origin.

The disadvantage of this method is that several features are calculated, and arbitrary heuristics may be introduced for calculating the characteristic quantities. By mean-value and standard-deviation calculation across all feature vectors for one whole audio file, the information being given by the feature vector's temporal form is reduced to a few feature quantities. This leads to a high information loss.

It is the object of the present invention to provide a method and an apparatus for extracting a signal identifier from a time signal which allow a meaningful identification of a time signal without too high an information loss.

This object is achieved by a method for extracting a signal identifier from a time signal as claimed in claim 1, or by an apparatus for extracting a signal identifier from a time signal as claimed in claim 19.

A further object of the present invention is to provide a method and an apparatus for creating a database of signal identifiers, and a method and an apparatus for referencing a search time signal by means of such a database.

This object is achieved by a method for creating a database as claimed in claim 13, an apparatus for creating a database as claimed in claim 20, a method for referencing a search time signal as claimed in claim 14, or an apparatus for referencing a search time signal as claimed in claim 21.

The present invention is based on the findings that in time signals having a harmonic portion, the time signal's temporal form may be used to extract a signal identifier of the time signal from the time signal, which signal identifier provides a good fingerprint for the time signal, on the one hand, and is manageable with regard to its data volume, on the other hand, to allow efficient searching through a plurality of signal identifiers in a database. An essential property of time signals having a harmonic portion are recurring signal edges in the time signal, wherein e.g. two successive signal edges having the same and/or a similar length enable an indication of the duration of a period and thus of a frequency in the time signal with a high resolution in terms of time and frequency, if not only the presence of the signal edges per se but also the temporal occurrence of the signal edges in the time signal is taken into account. It is thus possible to obtain a description of the time signal from the fact the time signal consists of frequencies successive in time. Using an audio signal as an example, the audio signal is thus characterized such that a sound, i.e. a frequency, is present at a certain point in time and that this sound, i.e. this frequency, is followed by another sound, i.e. another frequency, at a later point in time.

In accordance with the invention, a transition is thus made from the description of the time signal by means of a sequence of temporal samples to a description of the time signal by means of coordinate tuples of the frequency and the time of occurrence of the frequency. The signal identifier, or, in other words, the feature vector (fv) used for describing the time signal, thus includes a sequence of signal identifier values reflecting the time signal's temporal form more or less roughly, depending on the embodiment. Thus, the time signal is not characterized by its spectral properties, as in the prior art, but by the temporal sequence of frequencies in the time signal.

Thus, at least two detected signal edges are required for calculating a frequency value from the signal edges detected. The selection of these two signal edges from all of the signal edges detected, on the basis of. which frequency values are calculated, is manifold. Initially, two successive signal edges of essentially the same length may be used. The frequency value then is the reciprocal of the temporal interval of these edges. Alternatively, a selection may also be made by the amplitude of the signal edges detected. Thus, two successive signal edges of the same amplitude may be used for determining a frequency value. However, use need not always be made of two successive signal edges, but, for example, of the second, third, fourth, . . . signal edge of the same amplitude or length, respectively. Finally, it shall be noted that any two signal edges may be used for obtaining the coordinate tuples using statistical methods and on the basis of the superposition laws. The example of a flute shall illustrate that a tone issued by a flute provides two signal edges having a high amplitude, between which edges there is a wavecrest having a smaller amplitude. To determine the fundamental tone of the flute, the two signal edges detected may be selected, for example, by the amplitude.

In particular for audio signals, the temporal sequence of tones is the most natural form of characterization, since the essence of the audio signal is the very temporal sequence of tones, as may be seen, in the simplest manner, in musical signals. The most immediate perception a listener gets from a music signal is the temporal sequence of tones. It is not only in classical music, where a work is always built around a specific theme running all the way through the whole work in different variations, but also in songs of popular or other contemporary music that there is a catchy tune consisting in general of a sequence of simple tones, the theme, or the simple tune, being coined essentially by the recognizability independently of rhythm, pitch, any instrument accompaniment that may be employed, etc.

The inventive concept is based on this finding and provides a signal identifier which consists of a temporal sequence of frequencies or, depending on the form of implementation, is derived from a temporal sequence of frequencies, i.e. tones, by means of statistical methods.

An advantage of the present invention is that the signal identifier as a temporal sequence of frequencies represents a fingerprint of a high-scale information content for time signals having a harmonic portion and embodies, as it were, the gist or the core of a time signal.

Another advantage of the present invention is that although the signal identifier extracted in accordance with the invention represents a pronounced compression of the time signal, it still leans on the time signal's temporal form and is therefore adjusted to the natural perception of time signals, i.e. pieces of music.

Another advantage of the present invention is that due to the sequential nature of the signal identifier, it is possible to leave behind the distance-calculation referencing algorithms of the prior art and to use, for referencing the time signal in a database, algorithms known from DNA sequencing, and that in addition to this, similarity calculations may also be performed by using DNA sequencing algorithms having replace/insert/delete operations.

A further advantage of the present invention is that Hough transformation, for which efficient algorithms exit from the fields of image processing and image recognition, may be employed for detecting the temporal occurrence of signal edges in the time signal in a favorable manner.

A yet further advantage of the present invention is that the signal identifier of a time signal, which identifier has been extracted in accordance with the invention, is independent of whether the search signal identifier has been derived from the entire time signal or only from a portion of the time signal, since, in accordance with the algorithms of DNA sequencing, a comparison—which is effected step-by-step in terms of time—of the search signal identifier with a reference signal identifier may be carried out, wherein, due to the comparison sequential in time, the portion of the time signal to be identified is identified automatically, as it were, in the reference time signal where there is the most pronounced match between the search signal identifier and the reference signal identifier.

Preferred embodiments of the present invention will be explained below in more detail with reference to the accompanying figures, wherein:

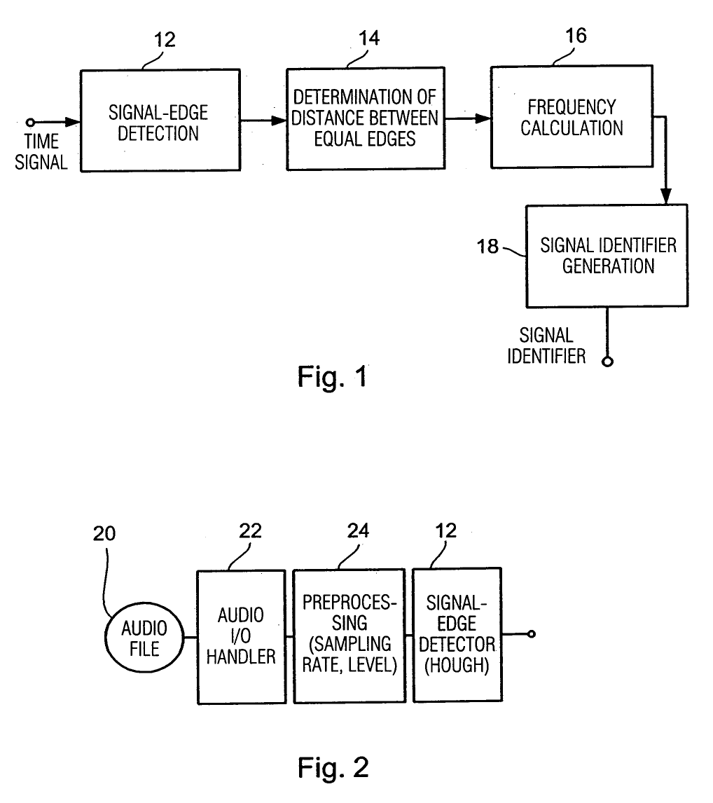

FIG. 1 is a block diagram of the inventive apparatus for extracting a signal identifier from a time signal;

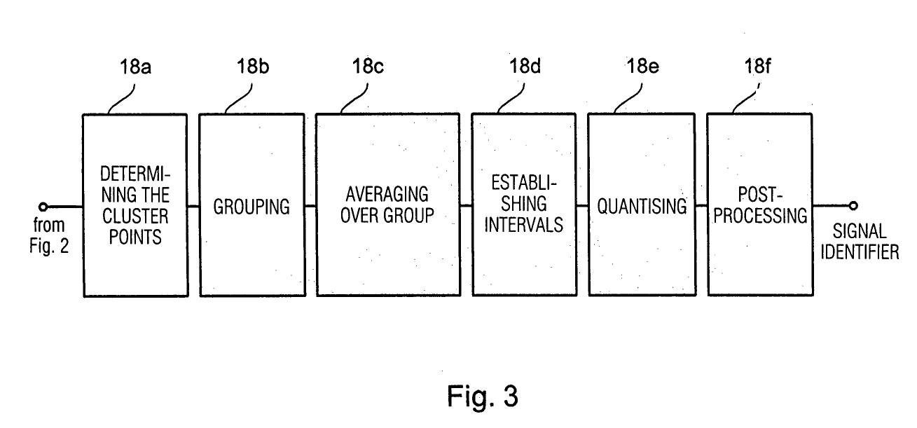

FIG. 2 is a block diagram of a preferred embodiment, the diagram being a representation of a preprocessing of the audio signal;

FIG. 3 is a block diagram of an embodiment for the creation of signal identifiers;

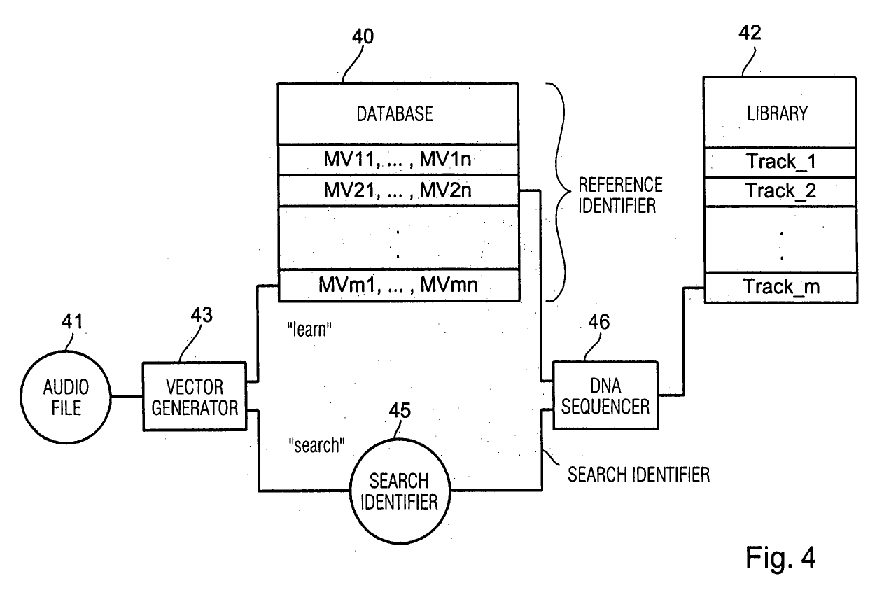

FIG. 4 is a block diagram of an inventive apparatus for creating a database and for referencing a search time signal in the database; and

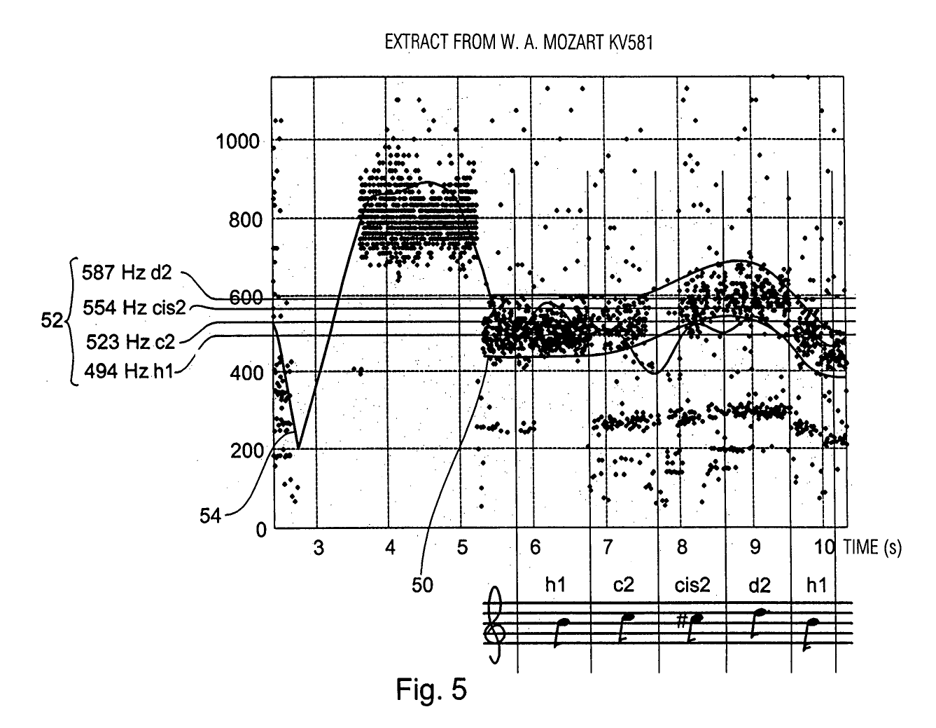

FIG. 5 is a graphic representation of an extract of Mozart KV 581 by means of frequency-time coordinate tuples.

FIG. 1 shows a block diagram of an apparatus for extracting a signal identifier from a time signal. The apparatus includes means 12 for performing a signal-edge detection, means 14 for determining the distance between two selected edges detected, means 16 for frequency calculation and means 18 for creating signal identifiers using coordinate tuples output from means 16 for frequency calculation, which tuples each have a frequency value and a time of occurrence for this frequency value.

It shall be noted at this point that even though an audio signal is referred to as a time signal below, the inventive concept is not suitable for audio signals only, but also for any time signals having a harmonic portion, since the signal identifier is based on the fact that a time signal consists of a temporal sequence of frequencies, in the example of the audio signal, of tones.

Means 12 for detecting the temporal occurrence of signal edges in the time signal preferably performs a Hough transformation.

Hough transformation is described in U.S. Pat. No. 3,069,654 by Paul V. C. Hough. Hough transformation serves to identify complex structures and, in particular, to automatically identify complex lines in photographs or other pictorial representations. Hough transformation is thus generally a technique that may be used for extracting features having a specific form within an image.

In its application in accordance with the present invention, Hough transformation is used for extracting signal edges having specified temporal lengths from the time signal. A signal edge is initially specified by its temporal length. In an ideal case of a sinus wave, a signal edge would be defined by the rising edge of the sine function of 0 to 90°. Alternatively, a signal edge may also be specified by the rise of the sine function of −90° to +90°.

If the time signal is present as a sequence of temporal samples, the temporal length of a signal edge corresponds to a certain number of samples if the sampling frequency with which the samples have been created is taken into account. Thus, the length of a signal edge may readily be specified by indicating the number of samples the signal edge is intended to comprise.

In addition, it is preferred to detect a signal edge as a signal edge only if same is steady and has a primarily monotonous form, i.e., in the case of a positive signal edge, if it has a primarily monotonously rising form. Of form, negative signal edges, i.e. monotonously falling signal edges, may also be detected.

A further criterion for classifying signal edges is to detect a signal edge as a signal edge only if it extends over a certain level range. In order to blank out noise disturbances it is preferred to specify a minimum level range or amplitude range for a signal edge, monotonously rising signal edges falling short of this level range not being detected as signal edges.

In accordance with a preferred embodiment of the present invention, for referencing audio signals, a further restriction is made to the effect that only such signal edges are searched whose specified temporal length is longer than a minimum cut-off length and shorter than a maximum cut-off temporal length. In other words, this means that only such signal edges are searched which indicate frequencies lower than a top cut-off frequency and higher than a bottom cut-off frequency. In pieces of music it is preferred to detect only such signal edges which indicate frequencies in the frequency range of 27.5 Hz (tone A2) to 4,186 Hz (tone c5). The tones provided by a common piano extend over this frequency range. This range of tones has proved sufficient for signal identifiers of pieces of music.

The signal-edge detection unit 12 thus provides a signal edge and the time of occurrence of the signal edge. It is irrelevant here whether what is taken as the time of occurrence of the signal of the signal edge is the time of the first sample of the signal edge, the time of the last sample of the signal edge, or the time of any other sample within the signal edge, as long as signal edges are treated equally.

Means 14 for determining a temporal interval between two successive signal edges whose temporal lengths are equal apart from a predetermined tolerance value examine the signal edges output by means 12 and extract two successive signal edges which are the same or essentially the same within a certain specified tolerance value. If such a simple sine tone is contemplated, a period of the sine tone is given by the temporal interval of two successive, e.g. positive, quarter waves of the same length. This provides the basis for means 16 to calculate a frequency value from the temporal interval determined. The frequency value corresponds to the inverse of the temporal interval determined.

Using this procedure, a representation of a time signal may be provided with a high resolution in terms of time, and at the same time, of frequency by indicating the frequencies occurring in the time signal and by indicating the times of occurrence corresponding to the frequencies. If the results of means 16 for frequency calculation are represented in a graphic manner, a diagram according to FIG. 5 is obtained.

FIG. 5 shows an extract of a length of about 13 seconds of the clarinet quintet A major, larghetto, KV 581 by Wolfgang Amadeus Mozart, as it would appear at the output of means 16 for frequency calculation. In this extract there are a clarinet playing a leading-tune solo part, and an accompanying string quartet. The result are the coordinate tuples as may be created by means 16 for frequency calculation, shown in FIG. 5.

Finally, means 18 serve to produce a signal identifier, which is favorable and suitable for a signal identifier database, from the results of means 16. The signal identifier is generally created from a plurality of coordinate tuples, each coordinate tuple including a frequency value and a time of occurrence so that the signal identifier includes a sequence of signal identifier values reflecting the time signal's temporal form.

As will be explained below, means 18 serve to extract the essential information from the frequency-time diagram of FIG. 5 which could be created by means 16, so as to produce a fingerprint of the time signal which is compact, on the other hand, and which is able to differentiate the time signal from other time signals in a sufficiently precise manner, on the other hand.

FIG. 2 shows an inventive apparatus for extracting a signal identifier in accordance with a preferred embodiment of the present invention. As a time signal, an audio file 20 is input into an audio I/O handler. The audio I/O handler 22 reads the audio file from a hard disc, for example. The audio data stream may also be read in directly via a soundcard. After reading-in a portion of the audio data stream, means 22 re-close the audio file and load the next audio file to be processed, or terminate the reading-in operation. The sequence of PCM samples (PCM=pulse code modulated), as are obtained, for example, from a CD, are then input into means 24 for preprocessing the audio signal. Means 24 serve to perform a sample rate conversion, if necessary, on the one hand, or serve to achieve a volume modification of the audio signal. Audio signals are present in different media in different sampling frequencies. As has already been explained, the time of occurrence of a signal edge in the audio signal is used for describing the audio signal, however, so that the sampling rate must be known in order to correctly detect the times of occurrence of signal edges, and, in addition, to correctly detect frequency values. Alternatively, a sample-rate conversion may also be performed by means of decimation or interpolation so as to bring the audio signals of different sample rates to one same sample rate.

In a preferred embodiment of the present invention, which is intended to be suitable for several sample rates, means 24 are therefore provided for performing sample-rate adjustment.

The PCM samples are additionally subject to automatic level adjustment which is also provided within means 24. Within means 24, the mean signal power of the audio signal is determined for automatic level adjustment in a look-ahead buffer. The audio signal portion present between two signal-power minima is multiplied by a scaling factor which is the product of a weighting factor and the quotient of the full-scale deflection and the maximum level within the segment. The length of the look-ahead buffer may vary.

Subsequently, the audio signal thus preprocessed is fed into means 12, which perform a signal-edge detection as has been described with reference to FIG. 1. Preferably, the Hough transformation is used for this purpose. A realization of the Hough transformation in terms of circuit engineering has been disclosed in WO 99/26167.

The amplitude of a signal edge determined by the Hough transformation, and the time of detection of a signal edge are then handed over to means 14 of FIG. 1. Within this unit, two successive detection times are subtracted from each other, respectively, the reciprocal of the difference of the times of occurrence being assumed as the frequency value. This task is performed by means 16 of FIG. 1 and, if a piece of music is processed accordingly, will lead to the frequency-time diagram of FIG. 5, wherein the frequency/time coordinate tuples obtained by Mozart, Köchel directory 581, are plotted.

In accordance with the invention, the presentation of FIG. 5 could already be used as a signal identifier for the time signal, since the temporal sequence of the coordinate tuples reflects the time signal's temporal form.

In one embodiment it is preferred, however, to perform postprocessing in order to extract, from the frequency-time diagram of FIG. 5, the essential information providing a fingerprint for the time signal which is as small but still as meaningful as possible, for signal referencing.

To this end, signal-identifier creating means 18 may be constructed as shown in FIG. 3. Means 18 are subdivided into means 18a for determining the cluster areas, into means 18b for grouping, into means 18c for averaging over a group, into means 18d for determining the interval(s), into means for quantizing 18e, and, finally, into means 18f for obtaining the signal identifier for the time signal.

As may be readily seen in FIG. 5, characteristic distribution-point clouds, referred to as clusters, are elaborated within means 18a for determining the cluster areas. This is done by deleting all isolated frequency-time tuples exceeding a predetermined minimum distance from the nearest spatial neighbor. Such isolated frequency-time tuples are, for example, the dots in the top right corner of the diagram of FIG. 5. This leaves a so-called pitch-contour stripe band which is outlined by reference numeral 50 in FIG. 5. The pitch-contour stripe band consists of clusters of a certain frequency width and length, it being possible for these clusters to be caused by tones played. These tones are indicated by horizontal lines intersecting the ordinate in FIG. 5 (52), in the example shown here, tones h1, c2, cis2, d2, and h1 occurring in the range between about 6 and 10 seconds in the sequence given. Tone al has a frequency of 440 Hz. Tone h1 has a frequency of 494 Hz. Tone c2 has a frequency of 523 Hz, tone cis2 has a frequency of 554 Hz, whereas tone d2 has a frequency of 587 Hz.

With polyphonic sounds, wider stripe bands result. The stripe width in single tones additionally depends on a vibrato of the musical instrument producing the single tones.

Within means 18b for grouping or forming blocks, the coordinate tuples of the pitch-contour strip are combined or grouped, band in a time window of n samples, to form a processing block to be processed separately. The block size may be selected to be equidistant or variable. Depending on the accuracy and memory space available for the signal identifier, a relatively course subdivision may be selected, for example a one-second raster, which corresponds, via the present sampling rate, to a certain number of samples per block, or a smaller subdivision. In order to take into account, with pieces of music, the underlying notation in the form of notes, the raster will alternatively always be selected such that one tone falls into the raster. To this end it is necessary to estimate the length of a tone, which is made possible by the polynomial fit function 54 depicted in FIG. 5. A group, or a block, will then be determined by means of the temporal interval between two local extreme values of the polynomial. In particular with relatively monophonic portions, this procedure provides relatively large groups of samples as occur between 6 and 12 seconds, whereas with relatively polyphonic intervals of the piece of music, wherein the coordinate tuples are distributed over a large frequency range, such as with 2 seconds in FIG. 5 or with 12 seconds in FIG. 5, smaller groups are determined, which in turn leads to the fact that the signal identification is performed on the basis of relatively small groups, so that the compression of information is smaller than in a rigid formation of blocks.

Within block 18c for averaging over a group of samples, a weighted mean value over all coordinate tuples present in a block is determined, as and when required. In the preferred embodiment, the tuples outside the pitch-contour strip band were “blanked out” already beforehand. Alternatively, however, this blanking out may also be dispensed with, which leads to the fact that all coordinate tuples calculated by means 16 are taken into account in the averaging performed by means 18c.

Within means 18d for determining the interval(s), a jumping width for determining the center of the next group of samples, i.e. the group of samples successive in time, is determined.

It shall be pointed out that within means 18c, either an arithmetic, a geometric or a median averaging may be performed.

Within quantizer 18e, the value having been calculated by means 18c is quantized into non-equidistant raster values. In pieces of music it is preferred to base the subdivision on the tone-frequency scale, the tone-frequency scale being subdivided, as has already been explained, in accordance with the frequency range provided by a common piano, extending from 27.5 Hz (tone A2) to 4,186 Hz (tone c5) and including 88 tone levels. If the value averaged and present at the output of means 18c is between two adjacent half-tones, it takes on the value of the nearest reference tone.

As a result, a sequence of quantized values is gradually yielded at the output of means 18e for quantizing, which values combine to form the signal identifier. As and when required, the quantized values may be postprocessed by means 18f, wherein postprocessing might comprise, for example, a correction of the pitch offset, a transposition into a different tone scale, etc.

In the following, reference will be made to FIG. 4. FIG. 4 schematically shows an apparatus for referencing a search time signal in a database 40, the database 40 comprising signal identifiers of a plurality of database time signals Track_1 to Track_m stored in a library 42 preferably separated from the database 40.

In order to be able to reference a time signal using the database 40, the database must initially be filled, which may be achieved in a “learn” mode. To this end, audio files 41 are fed to a vector generator 43 one by one, which comprises a reference identifier for each audio file and stores the reference identifier in the database such that it may be possible to recognize to which audio file, e.g. in library 42, the signal identifier belongs.

In accordance with the association shown in FIG. 4, signal identifier MV11, . . . , MV1n corresponds to time signal Track_1. Signal identifier MV21, . . . , MV2n belongs to time signal Track_2. Finally, signal identifier MVm1, . . . , MVmn corresponds to time signal Track_m.

The vector generator 43 is implemented to generally perform the functions depicted in FIG. 1, and is implemented, in accordance with a preferred embodiment, as depicted in FIG. 2 and 3. In the “learn” mode the vector generator 43 processes different audio files (Track_1 to Track_m) one by one in order to store signal identifiers for the time signals in the database, i.e. to fill the database.

In the “search” mode. an audio file 41 is to be referenced using database 40. To this end, the search time signal 41 is processed by the vector generator 43 to create a search identifier 45. The search identifier 45 is then fed into a DNA sequencer 46 so as to be able to be compared to the reference identifiers in the database 40. The DNA sequencer 46 is further arranged to make a statement about the search time signal with regard to the plurality of database time signals from library 42. Using search identifier 45, the DNA sequencer searches database 40 for a matching reference identifier and transfers a pointer to the respective audio file in library 42, which audio file is associated with the reference identifier.

DNA sequencer 46 thus performs a comparison of search identifier 45, or parts thereof, with reference identifiers in the database. If the specified sequence, or a partial sequence thereof, is present, the associated time signal is referenced in library 42.

Preferably, DNA sequencer 46 carries out a Boyer-Moore-algorithm, described, for example, in the specialist book “Algorithms on Strings, Trees and Sequences”, Dan Gusfield, Cambridge University Press, 1997. In accordance with a first alternative, a check for exact matching is performed. Making a statement therefore consists in saying that the search time signal is identical with a time signal in library 42. Alternatively or additionally, the similarity of two sequences may also be examined using replace/insert/delete operations and a pitch-offset correction.

Database 40 is preferably structured such that it is composed of the concatenation of signal-identifier sequences, the end of each vector signal identifier of a time signal being specified by a separator in order not to continue the search via time-signal file boundaries. If several matches are established, all referenced time signals are indicated.

Through the use of the replace/insert/delete operations, a similarity measure may be introduced, the time signal most similar to the search time signal 41 with regard to a specified measure of similarity being referenced in library 42. It is further preferred to determine a measure of similarity of the search audio signal to several signals in the library and subsequently to output the n most similar portions in the library 42 in a descending order.

1. Method for extracting a signal identifier from a time signal having a harmonic portion, the method comprising:
detecting (12) the temporal occurrence of signal edges in the time signal;
determining (14) a temporal interval between two selected detected signal edges;
calculating (16) a frequency value from the temporal interval determined, and associating the frequency value with a time of occurrence of the frequency value in the time signal to obtain a coordinate tuple from the frequency value and the time of occurrence for this frequency value; and
creating (18) the signal identifier from a plurality of coordinate tuples, each coordinate tuple including a frequency value and a time of occurrence, whereby the signal identifier includes a sequence of signal-identifier values which reflects the temporal form of the time signal.

2. Method as claimed in claim 1, wherein in the step of detecting (12), a signal-flank is detected as a signal-flank only if same has, over its specified temporal length, an amplitude larger than a predetermined amplitude threshold value.

3. Method as claimed in claim 1 or 2,
wherein in the step of detecting (12), a signal-flank is detected as a signal-flank only if its specified temporal length is longer than a minimum cut-off length and shorter than a maximum cut-off length.

4. Method as claimed in claim 3, wherein the time signal is an audio signal, and wherein the minimum temporal cut-off length is specified by means of a maximum audible cut-off frequency, and the maximum temporal cut-off length is specified by means of a minimum audible cut-off frequency.

5. Method as claimed in claim 3, wherein the time signal is an audio signal, and wherein the minimum temporal cut-off length is specified by means of a maximum tone frequency that may be created by an instrument, and the maximum temporal cut-off length is specified by means of a minimum tone frequency which may be created by an instrument.

6. Method as claimed in any one of the previous claims, wherein the step of creating (18) the signal identifier comprises:
eliminating (18a) coordinate tuples spaced apart by more than a predetermined threshold distance from an adjacent coordinate tuple in a frequency-time diagram so as to determine clusters of coordinate tuples.

7. Method as claimed in claim 5 or 6, wherein the step of creating (18) comprises:
grouping (18b) coordinate tuples in successive temporal intervals into blocks of coordinate tuples.

8. Method as claimed in claim 7, wherein the successive temporal intervals have a fixed and/or a variable length.

9. Method as claimed in claim 7 or 8, wherein the step of creating (18) the signal identifier comprises:
averaging (18c) the frequency values of coordinate tuples in the temporal intervals to obtain a sequence of averaged frequency values for a sequence of temporal intervals, the sequence of averaged frequency values representing a feature vector.

10. Method as claimed in claim 9, wherein step (18) of creating the signal identifier comprises:
quantizing (18e) the feature vector to obtain a quantized feature vector.

11. Method as claimed in claim 10, wherein the step of quantizing (18e) is performed using non-equidistantly distributed raster points, distances between two adjacent raster points being determined in accordance with a tone-frequency scale.

12. Method as claimed in any one of the previous claims, wherein in step (12) of detecting signal edges, a Hough transformation is employed.

13. Method for creating a database (40) from reference signal identifiers for a plurality of time signals, comprising:
extracting a first signal identifier for a first time signal by the method as claimed in any one of claims 1 to 12;
extracting a second signal identifier for a second time signal by means of a method as claimed in any one of claims 1 to 12; and
storing the extracted first signal identifier in association with the first time signal in the database (40); and
storing the extracted second signal identifier in association with the second time signal in the database (40).

14. Method of referencing a search time signal using a database (40), the database comprising reference signal identifiers of a plurality of database time signals, a reference signal identifier of a database time signal having been determined by a method as claimed in any one of claims 1 to 12, the method comprising:
providing at least one portion of a search time signal (41);
extracting (43) a search signal identifier from the search time signal by a method as claimed in any one of claims 1 to 12; and
comparing (46) the search signal identifier with the plurality of reference signal identifiers, and, in response to the step of comparing, making a statement about the search time signal with regard to the plurality of database time signals.

15. Method as claimed in claim 14, wherein in the step of making a statement, a search time signal is identified as a reference time signal if the search signal identifier matches at least a portion of a reference signal identifier.

16. Method as claimed in claim 14, wherein in the step of making a statement, a similarity between a search time signal and a database time signal is established if the search signal identifier and/or at least a portion of database signal identifier may be made to match by means of a reproducible manipulation.

17. Method as claimed in any one of claims 14 to 16,
wherein the database signal identifier comprises a sequence of database signal identifier values reproducing the temporal form of the database time signal,
wherein the search signal identifier comprises a search sequence of search signal identifier values reproducing the temporal form of the search time signal,
wherein the length of the database sequence is longer than the length of the search sequence, and
wherein the search sequence is sequentially compared to the database sequence.

18. Method as claimed in claim 17, wherein during the sequential comparing of the search sequence with the database sequence, a correction of the values of the search and/or the database signal identifier is performed by a replace, insert or delete operation of at least one value of the search and/or the database signal identifier to determine a similarity of the search time signal and the database time signal.

19. Method as claimed in any one of claims 14 to 18,
wherein the step of comparing (46) is performed using a DNA sequencing algorithm and/or using the Boyer-Moore algorithm.

20. Apparatus for extracting a signal identifier from a time signal having a harmonic portion, the apparatus comprising:
means for detecting (12) the temporal occurrence of signal edges in the time signal;
means for determining (14) a temporal interval between two selected detected signal edges;
means for calculating (16) a frequency value from the temporal interval determined, and for associating the frequency value with a time of occurrence of the frequency value in the time signal to obtain a coordinate tuple from the frequency value and the time of occurrence for this frequency value; and
means for creating (18) the signal identifier from a plurality of coordinate tuples, each coordinate tuple including a frequency value and a time of occurrence, whereby the signal identifier includes a sequence of signal-identifier values which reflects the temporal form of the time signal.

21. Apparatus for creating a database (40) from reference signal identifiers for a plurality of time signals, comprising:
means for extracting a first signal identifier for a first time signal by the method as claimed in any one of claims 1 to 12;
means for extracting a second signal identifier for a second time signal by means of a method as claimed in any one of claims 1 to 12; and
means for storing the extracted first signal identifier in association with the first time signal in the database (40); and
means for storing the extracted second signal identifier in association with the second time signal in the database (40).

22. Apparatus for referencing a search time signal using a database (40), the database comprising reference signal identifiers of a plurality of database time signals, a reference signal identifier of a database time signal having been determined by a method as claimed in any one of claims 1 to 12, the apparatus comprising:
means for providing at least one portion of a search time signal (41);
means for extracting (43) a search signal identifier by a method as claimed in any one of claims 1 to 12; and
means for comparing (46) the search signal identifier with the plurality of reference signal identifiers, and, in response to the step of comparing, making a statement about the search time signal with regard to the plurality of database time signals.
